(19) United States
(12) Patent Application Publication
(10) Pub. No.: US 2015/0097592 A1
(43) Pub. Date: Apr. 9, 2015

(54) DIRECT TESTING FOR PERIPHERAL CIRCUITS IN FLAT PANEL DEVICES

(71) Applicant: Photon Dynamics, Inc., San Jose, CA (US)

(72) Inventors: Chang Hee Lee, San Jose, CA (US); James Lee, San Ramon, CA (US); Sung Jin Kim, Santa Clara, CA (US); Jongho Lee, San Jose, CA (US); Michael Sean Cassady, San Jose, CA (US); Nikolay Mokichev, San Jose, CA (US); Kent Nguyen, San Jose, CA (US); Daniel Toet, Monte Sereno, CA (US)

(21) Appl. No.: 14/508,425

(22) Filed: Oct. 7, 2014

Related U.S. Application Data
(60) Provisional application No. 61/888,731, filed on Oct. 9, 2013.

(51) Int. Cl. G09G 3/00; G01R 31/44

(52) U.S. Cl. CPC G09G 3/006; G01R 31/44; G09G 3/007
USPC 324/760.02

(57) ABSTRACT

A method of testing a flat panel display including an array of pixels and a peripheral circuit configured to provide signals to the pixels is disclosed. The method includes applying at least one test signal to the peripheral circuit, acquiring one or more voltage images of the peripheral circuit, and detecting a defect in the peripheral circuit based on the acquired voltage images.

### CROSS-REFERENCES TO RELATED APPLICATIONS

The present application claims the benefit of U.S. provisional application No. 61/888,731, filed Oct. 9, 2013, and is related to commonly assigned U.S. Pat. No. 7,714,589, filed Nov. 14, 2006, which claims priority to commonly assigned U.S. Provisional Application No. 60/737,090, filed Nov. 15, 2005, the contents of all of which are incorporated herein by reference in their entirety.

### BACKGROUND

The present invention relates generally to inspection of thin film transistor (TFT) arrays used in liquid crystal, organic light emitting diode and related displays, and more specifically to the inspection of TFT arrays including integrated driving circuits.

A significant part of the manufacturing cost associated with liquid crystal display (LCD) panels occurs when the liquid crystal (LC) material is injected between the upper-color filter and lower-TFT backplane. It is therefore useful to identify and correct any defects in the TFT backplane, hereinafter also referred to as a “panel,” prior to this manufacturing step. Likewise, a significant part of the manufacturing costs associated with organic light emitting diode (OLED) displays occurs when the OLED material is deposited on the TFT backplane. The problem with inspecting LCD or OLED panels prior to deposition of the LC or OLED material is that without the LC or the OLED material, the display is not functional, and does not generate an image for inspection. Prior to deposition of LC or OLED material, the only signal present at a given pixel is the electric field generated by the voltage on that pixel's electrode, when driven by an external electrical source. Techniques to test arrays on panels typically take advantage of an electrical property of the pixel electrode, such as electrical field or pixel voltage as a function of changing drive voltages on the transistor gates or data lines.

Array panel testers devised by Photon Dynamics, Inc. (PDI)/Orbotech's Voltage Imagine® optical system (VIOS), as described by U.S. Pat. No. 4,983,911, for example, employ electro-optical transducers to translate the electrical fields on the devices under test into optical information recorded by an optical sensor in the VMS test head. Panel test machines (also known as Pattern Generators) electrically drive the panel using mechanical contacts to pads on the periphery of the panel in order to drive the signals used for inspection of the pixel array in conjunction with the VIOLS detector that detects the electric fields associated with the signals in the pixel array before the LC material is injected into the panel or OLED material is deposited onto the TFT backplane.

A large fraction of modem liquid crystal display (LCD) and organic light-emitting diode (OLED) display panels incorporate integrated gate driving (IGD) circuits that are fabricated as part of the TFT panel fabrication process, in contrast to displays having separate gate driver ICs that are attached to the panel near the end of the panel manufacturing process. The IGD circuits are typically formed in the periphery of the active pixel array area on the panel. The IGD technology lowers the costs, reduces the bezel size and weight and improves the robustness of the displays relative to displays with external, tab-bonded gate drive ICs. However, panel testing has been primarily directed to imaging the array region and not the IGD circuit area.

Thus, there is a need for a better method to detect defects in the IGD circuits in addition to the active array area in order to ensure proper functionality of the panel prior to LC material injection or OLED material deposition to maximize production yield and lower costs.

A better understanding of the nature and advantages of the embodiments of the present invention may be gained with reference to the following detailed description and the accompanying drawings.

### SUMMARY OF THE INVENTION

One inventive aspect is a method of testing a flat panel display including an array of pixels and a peripheral circuit configured to provide signals to the pixels. The method includes applying at least one test signal to the peripheral circuit, acquiring one or more voltage images of the peripheral circuit, and detecting a defect in the peripheral circuit based on the acquired voltage images.

Another inventive aspect is a system configured to test a flat panel display, the flat panel display including an array of pixels and a peripheral circuit configured to provide signals to the pixels. The system includes a probe assembly configured to apply at least one test signal to the peripheral circuit, a voltage imaging system configured to acquire one or more voltage images of the peripheral circuit, and a processor configured to detect a defect in the peripheral circuit based on the acquired voltage images.

### BRIEF DESCRIPTION OF THE DRAWINGS

FIG. 1 depicts a simplified high level block diagram of an array region in a panel being tested using a multitude of signal lines, a multitude of shorting bars, and a VMS test head.

FIG. 2 depicts the IGD circuit including a multitude of shift registers in the panel.

FIG. 3A depicts a timing diagram of a number of input signals applied to the IGD circuit of FIG. 2.

FIG. 3B depicts a timing diagram of a number of the output signals generated by the IGD circuit of FIG. 2.

FIG. 4A depicts a simplified simulated voltage image of an array region including a line defect associated with an IGD circuit defect in the panel.

FIG. 4B depicts a simplified simulated voltage image of an array region including a block defect associated with an IGD circuit defect in the panel.

FIG. 5 depicts a simplified high level block diagram of an IGD circuit in a panel being tested using a VMS test head while the panel is driven using a multitude of signal lines, in accordance with one embodiment of the present invention.

FIG. 6 depicts a simplified image of an exemplary shift register in an IGD circuit in the panel.

FIG. 7 depicts a simplified high level flow chart of a method for testing a flat panel display including an active array and a peripheral circuit including a multitude of periodically disposed unit cells formed in the panel, in accordance with one embodiment of the present invention.

FIG. 8 depicts a simplified high level flow chart of method steps depicted in FIG. 7, in accordance with another embodiment of the present invention.

FIG. 9 depicts a simplified high level flow chart of a method 900 according to an embodiment of the present invention.

FIG. 10 depicts a simplified high level schematic of a system 1000 according to some embodiments of the present invention.

### DETAILED DESCRIPTION

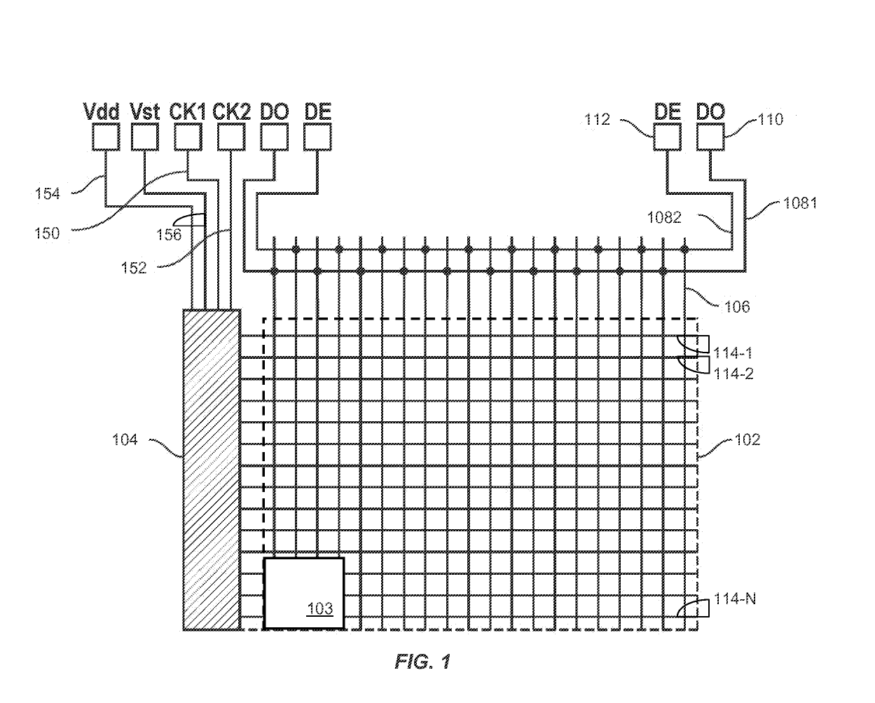

A method, in accordance with one embodiment of the present invention, includes an inspection technology for TFT display panels including integrated driving circuits. FIG. 1 depicts a simplified high level block diagram of an array region 102, hereinafter also referred to as “array of pixels,” in a panel being tested using a multitude of signal lines 150, 152, 154, 156, a multitude of shorting bars 1082, 1081, and a VIOS test head 103 disposed over array region 102, in accordance with one embodiment of the present invention. The panel further includes IGD circuits 104 disposed in the periphery of the array region 102, at one or both ends of the gate lines (FIG. 1 illustrates an IGD region on one side of the active area). IGD circuits 104 may be coupled to a first signal line 150, a second signal line 152, a third signal line 154, and a fourth signal line 156 that may be used to respectively supply a clock signal CR1, a clock signal CK2, a supply voltage Vdd, and an enable signal Vst to IGD circuits 104. When IGD circuit 104, in turn, supplies its output signal to N gate lines 114-1, 114-2, through 114-N, the IGD circuit and N gate lines are driven “as intended during panel operation,” that is, one gate line at a time responsive to the clock signals CK1, CK2, and enable signal Vst.

The panel may further include shorting bars 1081 and 1082 to drive a multitude of data lines 106 in parallel. The data lines are separated into a set of “odd” lines and “even” lines, which are connected respectively via shorting bars 1081 and 1082 to contact pads DO (“data odd”) 110 and DE (“data even”) 112. Pixels in array region 102, which are connected together with the same shorting bar, are turned on concurrently where intersecting data and gate lines are both activated, e.g., data “high.” Analogously, the panel may also include one or more gate shorting bars (not shown) connected to one or more gate pads (not shown) that allow the IGD circuit to be bypassed when the one or more gate shorting bars drive a multitude of gate lines directly in parallel. Shorting bars may be disconnected from the panel during the later stages of the panel fabrication process.

To electrically test a TFT array, a pattern of electric driving signals is applied and a means of detection, such as Photon Dynamics' voltage imaging system, (VIOS) scans over array region 102 of the panel observing any pixels that are not responding to the pattern of signals. The pattern of electric driving signals is applied to array region 102 through IGD circuits 104 or through the one or more gate shorting bars, and also to the data lines through the data shorting bars or individual data lines. The generated display pattern is compared to an expected display pattern to detect defects as described in greater detail in U.S. Pat. No. 7,714,589, to M. Jun, et al., titled “Array Test Using the Shorting Bar and High Frequency Clock Signal for the Inspection of TFT-LCD With Integrated Driver IC.”

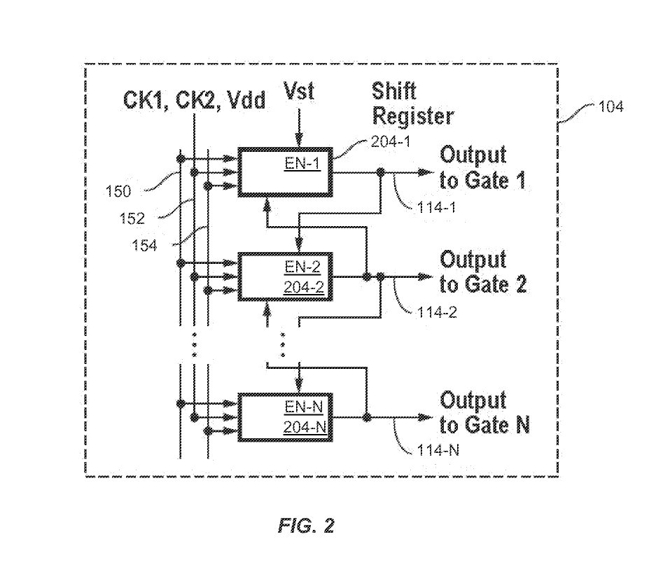

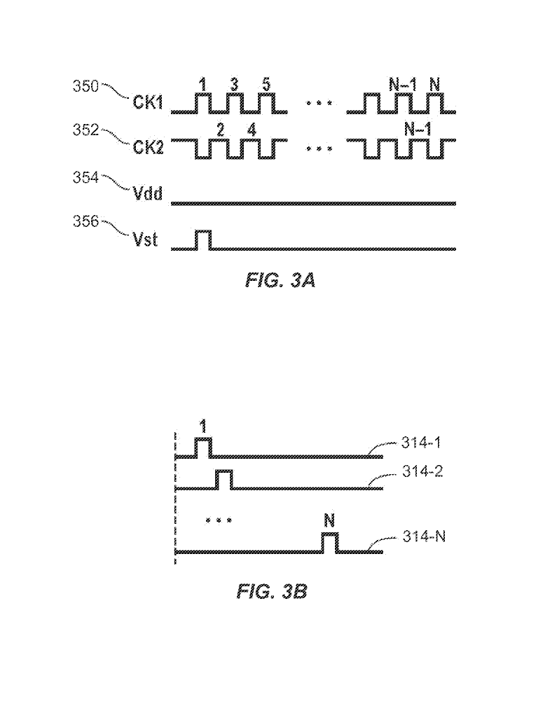

FIG. 2 depicts IGD an exemplary embodiment of periodic circuit 104 including a multitude of N shift registers 204-1 through 204-N (collectively and alternatively referred to herein as shift register 204) in the panel. In the following, “IGD circuit”, “IGD circuit elements” and “shift register” shall be understood to include the respective connections to corresponding gate lines 114 in array region 102. FIG. 3A depicts a timing diagram of a number of input signals applied to IGD circuit 104 of FIG. 2. FIG. 3B depicts a timing diagram of a number of the output signals generated by IGD circuit 104 of FIG. 2. Referring to FIG. 2, FIG. 3A, and FIG. 3B each shift register 204 receives a pair of clock signals CK1 350, CK2 352 that are phase shifted by 180 degrees relative to one another, and a supply voltage Vdd 354. When signal list 356 is applied to an input terminal EN-1 of shift register 204-1 and makes a low-to-high transition, shift register 204-1 generates an output pulse 314-1 that is shown as being supplied to gate line 114-1 (not shown). The output pulse 314-1 is synchronous with respect to the clock signals CK1 and CK2. In other words, signal Vst enables the start of the driving pattern. The output pulse of shift register 204-1 is received as an enabling signal EN-2 to shift register 204-2, which, in turn, supplies its output pulse 314-2 to gate line 114-2 (not shown), and so on through shift register 204-N. Accordingly, output pulses 314 are generated in a stepwise fashion in time, corresponding to the stream of input clock signals CK1 and CK2. This is one example of an “as intended” operation.

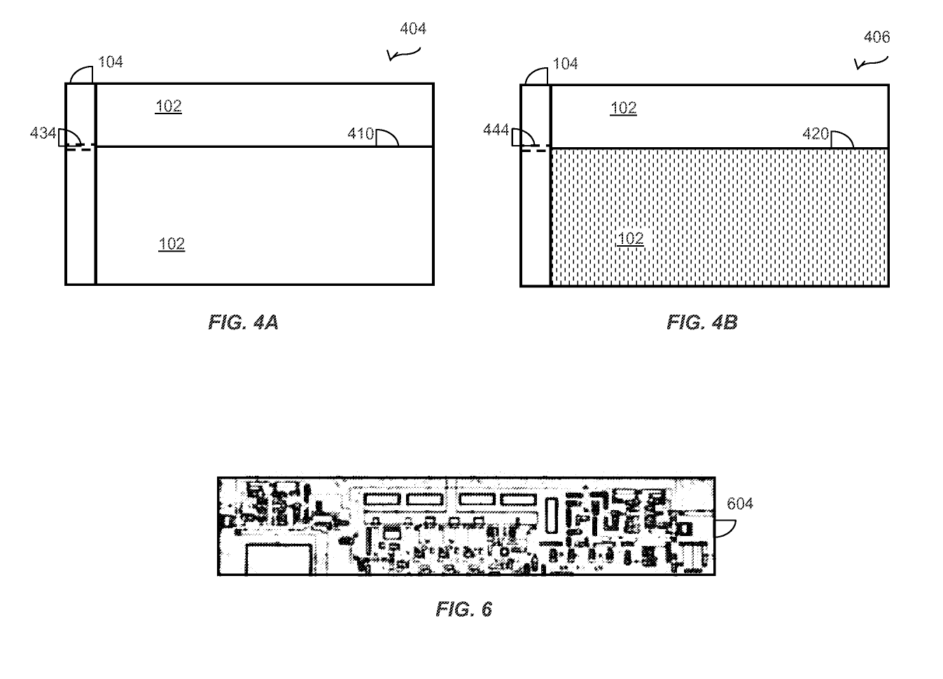

FIG. 4A depicts a simplified simulated voltage image 404 of array region 102, observed for example by a VIOS test head, including a line defect 410 associated with an IGD circuit 104 defect in the panel. “Line-type” defect 410 is the result of a defect in the associated shift register 434 in IGD circuit 104 and is detected as a result of one of the N gate lines 114 having a substantially different voltage condition than other (i.e., the non-defective) gate lines 114. FIG. 4B depicts a simplified simulated voltage image 406 of an array region 102 including a “block-type” defect 420 associated with another type of IGD circuit 104 defect in the panel. Block defect 420 is the result of a defective shift register 444 associated with one of the N gate lines 114 and the gate lines that are supposed to be driven after the gate line that has defective shift register 444, which all have a substantially different voltage condition from the normal gate line voltages driven before the defective gate line. Shift registers 434 and 444 may for example, correspond to one of the shift registers 204 depicted in FIG. 2. Line defect 410 and block defect 420 are located by moving VIOS test head 103 referenced in FIG. 1 over region 102.

Defects in the array region 102, which may be hidden by defects in IGD circuit 104, may be detected by driving the gate lines using a conventional shorting bar, which allows the IGD circuit to be bypassed and provides normal voltage levels to drive gate lines 114.

The techniques described above have enabled significant improvements in IGD defect detection, but still have significant limitations, such as related to locating a specific defective element of the IGD, e.g., within a shift register containing the defect, because IGD defects may have widely varying signatures depending on their exact nature. Some IGD defects may lead to a change (increase or decrease) of the voltage in the entire area of the panel downstream of the defect, while others may lead to a change in voltage over an area that is limited to a band (e.g., the voltage increases to normal again below a certain gate index N). Other IGD defects may be characterized by one or more isolated lines having lower (or higher) than normal voltage. Furthermore, in certain cases, the impact of the IGD defect on array region 102 may be weak and thus difficult to detect.

In accordance with one embodiment of the present invention, a new IGD defect detection method provides direct voltage imaging of the structures in the IGD area. In other words, in some embodiments, the new IGD defect detection method acquires a voltage image directly from the peripheral circuit region, in contrast to inferring IGD defects from a direct voltage image of array region 102 (i.e., indirect IGD defect detection). The new IGD defect detection method not only provides more accurate detection and localization of defective IGD circuit elements (e.g., it allows to determine which shift register is defective), but may also provide the ability to determine when in the defective shift register the defect is located. Further, the new IGD defect detection method may identify which of the many elements (e.g. more than about 10 transistors) of the shift registers is defective. In one embodiment, the peripheral circuit region may include a multitude of interface connections disposed between the multitude of shift registers 204 and array region 102. In one embodiment, the multitude of interface connections may include a portion of gate signal lines 114 and the signal lines between shift registers, which may be disposed between the shift registers 204 and array region 102.

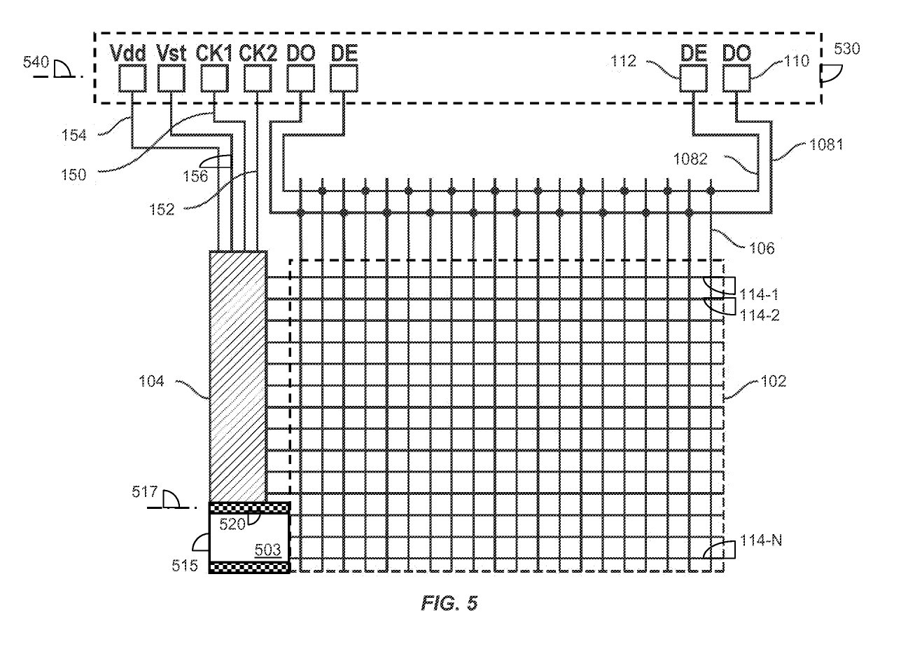

FIG. 5 depicts a simplified high level block diagram of IGD circuit 104 in a panel being tested using a VIOS test head 503 while the panel is driven using a multitude of signal lines 150, 152, 154, in accordance with one embodiment of the present invention. Features depicted in FIG. 5 are similar to features depicted in FIG. 1. Certain differences are discussed below.

When signals are applied to IGD circuit 104, the conductive elements included in IGD circuit 104 are subject to voltages, which cause electric fields to emanate from the surface of the display in the area of the IGD circuit. These electric fields may be imaged using a VIOS test head 503 positioned (at least in part) directly above the peripheral area of the panel containing the IGD, analogous to how pixels in the active area are tested before LC material is injected into the panel. However, VIOS test head 503 is positioned in such a way as not to interfere with probe contacts and associated hardware that couple the multitude of signals to the panel.

One aspect of the implementation of direct Voltage Imaging of IGD circuits is the ability to avoid mechanical interference between the VIOS test head, which moves across the surface of the panel, and the probe assembly. This may he addressed in several ways discussed below.

In one embodiment, VIOS test head 503 includes at least one air injector block 520 adapted to float VIOS test head 503 on a cushion of air at a predetermined distance above the panel without interfering with a mechanical probe assembly and associated hardware (not shown) adapted to couple the multitude of signals to the panel. Further, air injector block 520 is part of the physical area, but not the imaging area of VIOS test head 503, implying that the area of VIOS test head 503 may exceed the area to he imaged (e.g., in this case, IGD circuit 104). This in turn may result in the probing hardware of the probe assembly having a minimal separation from the IGD circuit (or equivalently, the panel active area), which may lead to inefficient utilization of the substrate area. In one embodiment, air injector block 520 may be disposed along at least one side of VIOS test head 503 adapted to provide VIOS test head 503 with a detection surface abutting or directly abutting a different side 515 of VIOS test head 503. In one embodiment, air injector block 520 may be oriented along a longitudinal axis 517 oriented substantially parallel to gate lines 114 of the panel. VIOS test head 503 or the panel plate may also be rotated to ensure that the effective area imaged by the detection modulator in the VIOS test head 503 extends out farthest towards the edge of the panel without the occlusion area caused by air injector block 520 interfering with the acquisition of voltage images at the edge of the panel.

In one embodiment, the panel may include a multitude of contact pads 530 adapted to be probed mechanically and further adapted to not interfere and to allow for a probe assembly connected thereto to not interfere with the motion of VIOS test head 503 when the mechanical probe assembly (including the probe pins themselves) is in contact with multitude of contact pads 530. For example, multitude of contact pads 530 may be disposed in at least one row on a side of the panel away from IGD circuits 104 and array region 102. In one embodiment, multitude of contact pads 530 may be disposed in the periphery outside array region 102 on a side substantially orthogonal to the direction of data lines 106, e.g., the longitudinal axis 540 of the at least one row of contact pads 530 is substantially orthogonal to the longitudinal direction of data lines 106. In one embodiment, the probe assembly may be adapted to minimize mechanical interference with VIOS test head 503. For example, the probe assembly may use small probe pins and small probe pins holders.

In one embodiment, during VIOS testing, IGD circuits 104 may be driven using the pattern(s) used for normal or “as intended” operation referenced in FIG. 3A and FIG. 3B. In another embodiment, during VIOS testing, IGD circuits 104 may be driven using special patterns used to accentuate certain type of defects. For example, a short in a channel of a TFT in a given shift register may be detected when the gate of the TFT is driven low, while the source of the TFT is kept high using at least one of the signal lines 150, 152, 154, and/or 156, driving IGD circuits 104. Other patterns may be designed to detect different types of defects.

FIG. 6 depicts a simplified image 604 of an exemplary shift register in an IGD circuit in the panel, illustrating that the structure of IGD circuit 104 is generally more complex than that of array region 102. However, as depicted in FIG. 2, IGD circuit 104 is periodic in the direction perpendicular to gate lines 114 with a periodicity that is an integer multiple of the gate line period (this integer typically being equal to 1 or 2). For example, the integer multiple may be 2 when the layout design pattern for an even number indexed shift register (e.g., shift register 204-2) is flipped 180 degrees along a axis parallel to gate lines 114 compared to an odd number indexed shift register (e.g., shift register 204-1). The periodically disposed unit cell, corresponding to shift registers 204, of this peripheral circuit structure is complex. Therefore, different algorithms than those used for defect detection in array region 102 are needed.

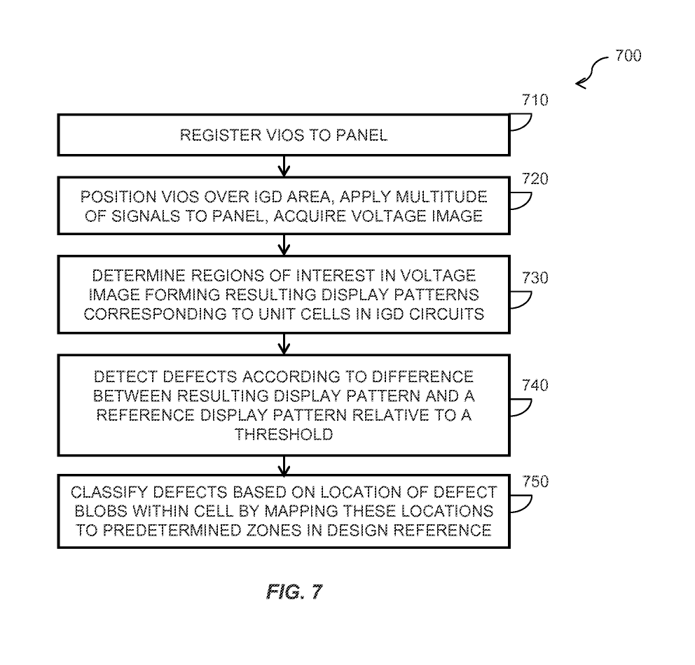

FIG. 7 depicts a simplified high level flow chart 700 of a method for testing a flat panel display including an active array and a peripheral circuit region including a multitude of periodically disposed unit cells formed in the panel, in accordance with one embodiment of the present invention. Referring to FIG. 2 and FIG. 5, after registering 710 VIOS test head 503 to the panel by means of alignment fiducial marks implemented for this purpose in the panel periphery, VMS test head 503 is positioned 720 above the IGD area; a multitude of signals may be applied to the panel, and VIOS test head 503 acquires voltage images of the IGD area resulting from the applied signals. The voltage images are used to determine the functionality of the IGD area.

In some embodiments, in accordance with the resulting registration data and layout information associated with the locations of periodic circuits on the panel (e.g., the locations of shift registers 204 on the panel), regions of interest (ROI's) in the voltage image associated with each of the multitude of periodically disposed unit cells (e.g., the N shift registers 204) in the periphery (e.g., IGD circuit 104) of the panel may be determined 730. In some embodiments, in accordance with the spatial period of the periodic circuits on the panel, as determined from either layout information or the voltage image, the regions of interest (ROI's) in the voltage image are determined 730. Resulting display patterns may be formed. Defects are detected 740 according to a difference between the resulting display patterns and an expected or reference display pattern and further in accordance to a threshold level to he described in more detail below.

The location of a defect blob within a IGD circuit element ROI may be used to classify 750 the defect based on comparison with the layout information of the panel. This can he done by subdividing the layout information into various zones, corresponding to features (e.g., transistors or groups of transistors) of shift register 204, and determining which zone the detect corresponds to by mapping the defective cell (shift register) onto the layout information. The classification accuracy increases as a function of the effective resolution of the VIOS.

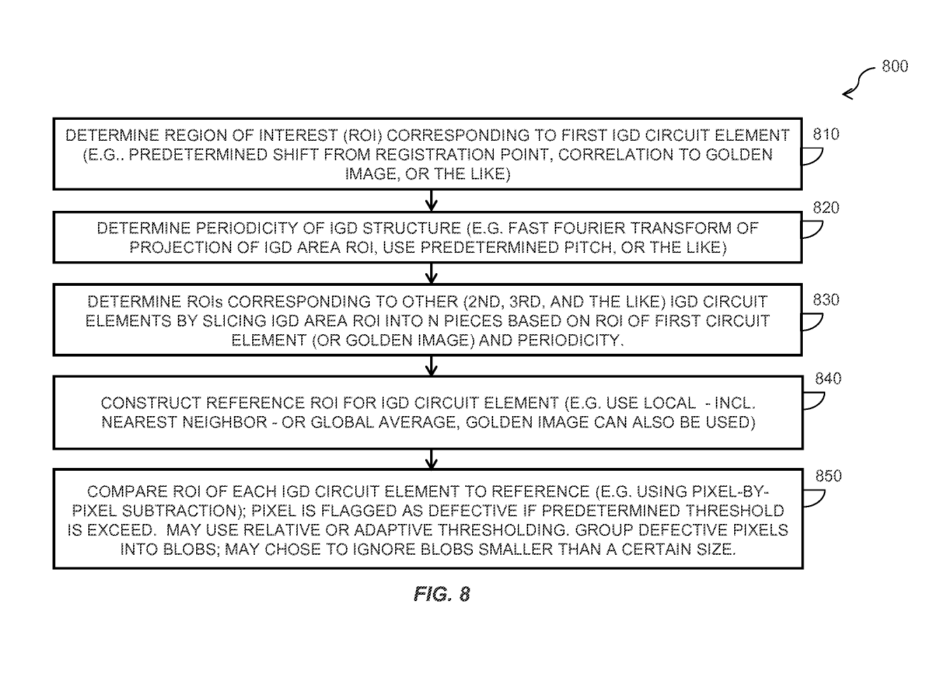

FIG. 8 depicts a simplified high level flow chart 800 of method steps 730 and 740 depicted in FIG. 7, in accordance with another embodiment of the present invention. After registration and acquisition of the Voltage Image, the ROI corresponding to a first IGD circuit element or nit cell (e.g. the unit cell closest to the registration point) may be determined 810. The first unit cell determination may be done in accordance with a predetermined shift relative to the registration point, or by correlating the part of the image containing the reference point and the first element to a reference or “golden” image (e.g., a stored voltage image of a known non-defective unit cell or shift register and the registration mark).

Subsequently, the periodicity of the periodically disposed unit cells (e.g., shift registers 204) may be determined 820. The periodicity determination may be done for instance by performing a projection along the direction of repetition of periodically repeating unit cells (e.g., in the direction orthogonal to longitudinal axis of gate lines 114) of the ROI corresponding to the first IGD circuit element or unit cell followed, for example, by a Fast Fourier Transformation. A predetermined pitch between the unit cells or the IGD circuit elements (e.g. determined using the layout information) may also be used.

In the next step, the ROIs corresponding to the IGD circuit elements or unit cells after the first unit cell (e.g., the second, third, and/or so on unit cells) may be determined 830. The determination of ROIs after the first may be done by slicing the ROI of the IGD circuit into N sub-ROIs in accordance with the ROI of the first unit cell or the golden image and the periodicity detected in the prior step 820

A reference ROI for the IGD circuit elements may be constructed 840 next. This reference ROI may be formed in accordance with the golden image or may be constructed by averaging all or some of the IGD circuit element ROIs. This reference could, for example, be in the form of a median projection peak (or valley) intensity. For example, the reference ROI may be constructed exclusively from unit cell elements in close proximity (e.g., the nearest neighbors) of any given unit cell or IGD circuit element. Constructing the reference ROI from unit cell elements in close proximity may be called local averaging, which may be used to minimize the impact of long-range variations. Alternatively, in one embodiment, global averaging over the multitude of unit cells may be used In one embodiment, outlier unit cells (e.g. defective unit cells with compromised voltage images) may be rejected When forming the reference.

The so-formed reference ROI may be compared 850 to (e.g. subtracted from) each of the multitude of unit cell or IGD circuit element ROI to detect defects. As an example, one may compare the intensity of each projection peak or valley to a reference (e.g. median) projection peak intensity. The comparison may be done in accordance with a sensor pixel-by-sensor pixel subtraction. Low pass filtering may be used to minimize the impact of noise in the image data. Defective cells are identified as the cells in which the difference with the reference or neighbor exceeds a predetermined threshold or series of predetermined thresholds at any location in the cell for any given pixel in the ROI. The predetermined thresholds may be set relative to an absolute number, to the intensity of the reference ROI, or in accordance with the variation between the individual IGD ROIs that compose the reference ROI—the latter approach is called “adaptive thresholding”. Other “thresholding” approaches may also be envisioned. The defective pixels are grouped into connected elements called blobs. Defect blobs may be disregarded based on their size (e.g. blobs formed of fewer than a certain number of connected sensor pixels may be ignored) or other criteria.

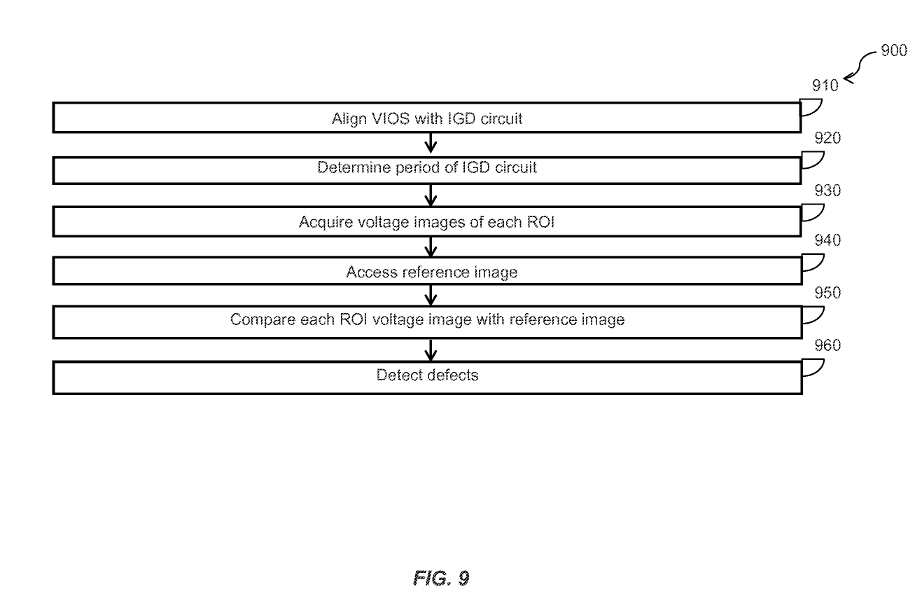

FIG. 9 depicts a simplified high level flow chart of a method 900 according to an embodiment of the present invention. Using the method 900, defects in a periodic circuit, such as an IGD circuit of an FPD, may be detected. According to the method, a voltage imaging system, for example, a VMS test head, such as those discussed elsewhere herein, is used to capture voltage images of the periodic circuit, which has been driven with electronic input signals configured to cause one or more nodes of the periodic circuit to assume a known voltage state. if properly functioning. One or more aspects of other methods discussed herein may be used in the method 900.

The voltage imaging system may be aligned (or registered) with the periodic circuit 910. For example, the voltage imaging system may be aligned using an optical feature recognition control system. For example, an optical feature recognition control system may be configured to match a physical feature of the periodic circuit with a feature pattern stored in a memory. For example, one or more alignment fiducial marks, or another pattern may be generated as part of the physical periodic circuit. A representation of the marks or pattern is stored in the memory, and the voltage imaging system is aligned such that the voltage imaging system generates an image of the physical marks or pattern which matches and is positionally aligned with the representation of the marks or pattern in the memory.

Alternatively, the periodic circuit may be physically positioned so that the alignment fiducial marks or other pattern is within the field of view of the optical feature recognition system. The position of the marks or pattern is then registered with high accuracy using the optical feature recognition system. Using the known offset between the voltage imaging system and the optical feature recognition system, the offset between the alignment marks or pattern and the first portion of the periodic circuit to be inspected by the voltage imaging system is determined. Based on the offset, the voltage imaging system is positioned on the first portion of the periodic circuit.

Other alignment mechanisms and schemes may additionally or alternatively be used. For example, a user may input information representing alignment information for positioning the voltage imaging system, or information representing positioning for alignment may be stored in a memory.

In addition, the spatial period of the periodic circuit is determined 920. For example, the spatial period may be determined based on one or more voltage images of the periodic circuit acquired using the voltage imaging system. The one or more images may be analyzed by a processor to determine the period of the periodic circuit. For example, a Fast Fourier Transform (FFT) may be performed on data of the voltage images to determine the spatial period of the periodic circuit in a direction for which the determined spatial period represents a length of a repeated unit cell of the periodic circuit. In some embodiments, the data of the voltage images includes a projection along the direction of the repeated cells of the periodic circuit.

Other methods of determining the period of the periodic circuit may additionally or alternatively be used. For example, a user may input information representing the spatial period, or information representing the spatial period may be stored in a memory.

The period of the periodic circuit may be used to determine a dimension for each of multiple regions of interest (ROI's). For example, a length of each ROI or a pitch of the ROI's may correspond with or be equal to one spatial period of the periodic circuit. In some embodiments, the length of each ROI or the pitch of the ROI's may correspond with or be equal to an integer number of spatial periods of the periodic circuit.

Based on the length or pitch information and the alignment information, the locations of each ROI may be determined. Once the locations of the ROI's are determined, at least one voltage image is accessed for each ROI 930. In some embodiments, the one or more voltage images of the periodic circuit used for determining the spatial period of the periodic circuit are accessed. In some embodiments, one or more voltage images for the ROI's is acquired using the voltage imaging system by causing the voltage imaging system to acquire one or more new voltage images.

The method also includes accessing a reference image 940. For example, in some embodiments, the reference image is stored in a memory in communication with the processor. For example, using the voltage imaging system, a voltage image of a known good portion of the periodic circuit may be captured, and the reference image may be generated based on the captured voltage image and stored in the memory.

In some embodiments, the reference image may be generated based on voltage images of the device being tested. For example, voltage images of all or some of the ROI's may be averaged to generate the reference image. Alternatively, the average height of the projection may be used for generating the reference image.

Once the reference image is accessed, the voltage image of each ROI is compared with the reference image 950.

Based on the comparisons, each ROI may be assessed as being either operational or defective 960. For example, ROI's whose voltage images differ from the reference image by more than a threshold may be assessed as including one or more defects. In addition, ROI's whose voltage images differ from the reference image by less than the threshold may be assessed as being operational.

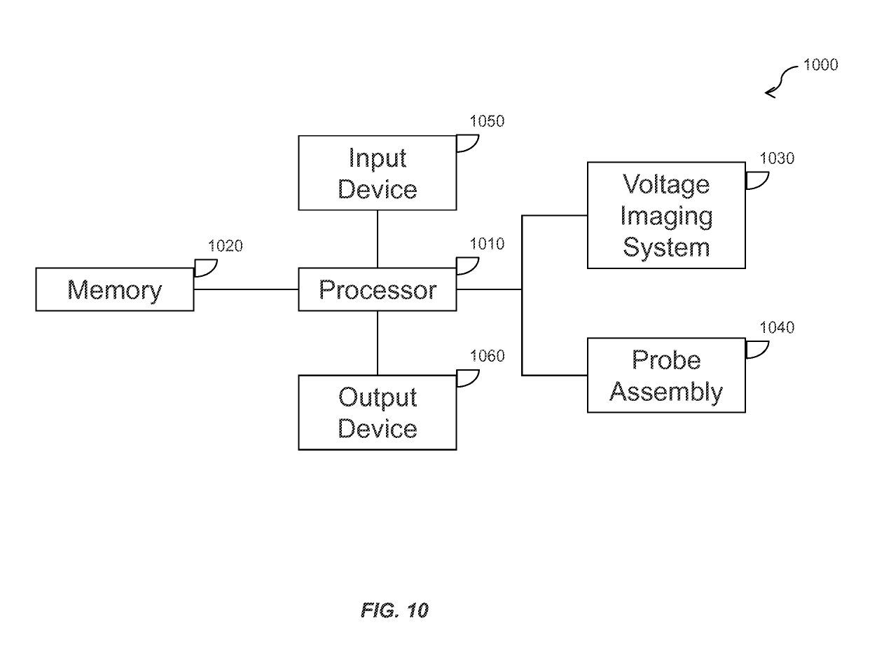

FIG. 10 depicts a simplified high level schematic of a system 1000 according to some embodiments of the present invention. System 1000 includes processor 1010, electronic memory 1020, voltage imaging system 1030, probe assembly 1040, input device 1050, and output device 1060.

Processor 1010 is in electrical communication with each of memory 1020, voltage imaging system 1030, probe assembly 1040, input device 1050, and output device 1060. Processor 1010 is configured to interact with each of memory 1020, voltage imaging system 1030, probe assembly 1040, input device 1050, and output device 1060 so as to cause the system 1000 to perform the method steps and actions discussed herein. Processor 1010 may be configured to execute instructions stored in memory 1020, which are configured to cause the system 1000 to perform the method steps and actions discussed herein.

Input device 1050 is configured to be used by a user to communicate information to processor 1010. For example, input device 1050 may include a keyboard.

Output device 1060 is configured to receive information from processor 1010 and to communicate the received information to a user. For example, output device 1060 may include a display.

Electronic memory 1020 may store computer readable instructions, which, when executed, for example by processor 1010, cause the processor 1010, or the system 1000 to perform the methods and actions discussed herein. Electronic memory 1020 may also store other information so as to function as the various memories discussed elsewhere herein.

Voltage imaging system 1030 may be configured to perform the methods and actions performed by the various voltage imaging systems discussed herein. For example, voltage imaging system 1030 may include a VIOS test head.

Probe assembly 1040 may be configured to perform the methods and actions performed by the various probe assemblies discussed herein.

With the introduction of direct Voltage imaging of IGD circuits, in accordance with embodiments of the present invention, the inspection of array region 102 may be done entirely using a shorting bar to bypass IGD circuits 104. Therefore, for an inspected site including both a portion of the IGD circuit and a portion of array region 102, two sets of Voltage Images may be acquired. in one embodiment, the two sets of Voltage images may include one Voltage Image obtained with the full-gate pattern using the IGD circuits 104 as intended and another one obtained with the bypass pattern. The subsequent image processing may be apportioned to the ROIs corresponding to the areas for which the patterns are intended (e.g., full gate pattern for IGD, bypass pattern for active area).

The embodiments of the present invention may be applied to detection of defects in TFT integrated data driver circuits when such data drivers are implemented in production. The embodiments of the present invention may be used with voltage measurement technologies other than Electro-Optical Transducer-based ones. One example of such alternative technologies is voltage measurement by secondary electrons generated after exposure of the panel structures to an electron beam.

It is understood that the embodiments of the present invention are not limited to finding defects in the IGD circuits, but may be applicable to find defects in any periodically repeating complex circuit structure disposed in the periphery region of the panel outside array region 102.

The above embodiments of the present invention are illustrative and not limiting. Various alternatives and equivalents are possible. Although, the invention has been described with reference to an integrated gate driving circuit by way of an example, it is understood that the invention is not limited by the type of periodic circuit in the periphery of the flat panel. Although, the invention has been described with reference to LCD and OLED display panels by way of examples, it is understood that the invention is not limited by the type of display panel technology. Although, the invention has been described with reference to a Voltage Imaging® optical system (VIOS) test head by way of an example, it is understood that the invention is not limited by the type of voltage imaging technology used. Further, the invention may be used in testing applications not .limited to the testing of thin-film-transistor arrays, such as other circuits on flat panels, microelectronic circuits, circuit boards, solar panels, semiconductor circuits, and so on. Other additions, subtractions, or modifications are understood in view of the present disclosure and are intended to fall within the scope of the disclosure.

What is claimed is:

1. A method of testing a fiat panel display comprising an array of pixels and a peripheral circuit configured to provide signals to the pixels, the method comprising:
applying at least one test signal to the peripheral circuit;
acquiring one or more voltage images of the peripheral circuit; and
detecting a defect in the peripheral circuit based on the acquired voltage images.

2. The method of claim 1, wherein the peripheral circuit includes a plurality of periodically disposed unit cells, and wherein each voltage image is of one of the unit cells.

3. The method of claim 2, further comprising determining the period of the periodically disposed unit cells.

4. The method of claim 3, wherein the period is determined based on the one or more voltage images.

5. The method of claim 4, wherein the period is determined based on a Fast Fourier Transform of the one or more voltage images.

6. The method of claim 2, further comprising comparing each voltage image with a reference, wherein detecting the defect comprises detecting a difference between one or more of the voltage images and the reference.

7. The method of claim 6, further comprising determining the reference.

8. The method of claim 7, wherein the reference is determined based on the voltage images.

9. The method of claim 8, wherein the reference is determined based on an average of the voltage images.

10. The method of claim 1, wherein the peripheral circuit comprises:
a plurality of shift registers; and
a plurality of interface connections disposed between the plurality of shift registers and the array of pixels.

11. A system configured to test a flat panel display, the flat panel display comprising an array of pixels and a peripheral circuit configured to provide signals to the pixels, the system comprising:
a probe assembly configured to apply at least one test signal to the peripheral circuit;
a voltage imaging system configured to acquire one or more voltage images of the peripheral circuit; and
a processor configured to detect a defect in the peripheral circuit based on the acquired voltage images.

12. The system of claim 11, wherein the peripheral circuit includes a plurality of periodically disposed unit cells, and Wherein each voltage image is of one of the unit cells.

13. The system of claim 12, wherein the processor is further configured to determine the period of the periodically disposed unit cells.

14. The system of claim 13, wherein the period is determined based on the one or more voltage images.

15. The system of claim 14, wherein the period is determined based on a Fast Fourier Transform of the one or more voltage images.

16. The system of claim 12, wherein the processor is further configured to compare each voltage image with a reference, and wherein detecting the defect comprises detecting a difference between one or more of the voltage images and the reference.

17. The system of claim 16, wherein the processor is further configured to determine the reference.

18. The system of claim 17, wherein the reference is determined based on the voltage images.

19. The system of claim 18, wherein the reference is determined based on an average of the voltage images.

20. The system of claim 11, wherein the peripheral circuit comprises:
a plurality of shift registers; and
a plurality of interface connections disposed between the plurality of shift registers and the array of pixels.
